(19) United States
(12) Patent Application Publication
(10) Pub. No.: US 2017/0077374 A1
(43) Pub. Date: Mar. 16, 2017

(54) BiSbTeSe-based Thermoelectric Material

(71) Applicant: Leizig (Guangdong) Thermoelectric Technologies Co., Ltd., Yingde (CN)

(72) Inventors: Yiping Luo, Yingde (CN); Bin Lin, Yingde (CN)

(21) Appl. No.: 14/935,452

(22) Filed: Nov. 9, 2015

(30) Foreign Application Priority Data
Sep. 11, 2015 (CN) 201510579429.5

(51) Int. Cl. H01L 35/16; C22C 1/02; C22C 1/05; H01L 35/18; H01L 35/34

(52) U.S. Cl. CPC H01L 35/16; H01L 35/18; H01L 35/34; C22C 1/05; C22C 1/02

(57) ABSTRACT

The present invention discloses a BiSbTeSe-based thermoelectric material, whose general formula is BiₘSbₙTeₓSe_{y}M_{z}; wherein, m=0.4-0.6, n=1.4-1.6, x=2.7-2.9, y=0.075-0.3, z=0.02-0.15, M is one or more elements of S, Si, P, Ge, Sn, Ce, Li, I, Br, Al, Cu, Ag, Yb, Tm, La, Gd and Dy. The BiSbTeSe-based thermoelectric material is prepared through powder mixing, alloy smelting and other steps. The BiSbTeSe-based thermoelectric material in the present invention has the advantages of low thermal conductivity and good thermoelectric properties, which expands the application area of thermoelectric material.

### CROSS-REFERENCE TO RELATED PATENT APPLICATION

The present patent application claims benefit of Chinese patent application No. 201510579429.5 filed on Sep. 11, 2015, the entire contents of which are incorporated by reference.

### TECHNICAL FIELD

The invention relates to new energy materials and its manufacture technology field, specifically relates to a BiSbTeSe-based thermoelectric material, which is made of BiSbTe, Se and another one or more metallic element.

### BACKGROUND

In recent years, with the rapid population growth and rapid industrial development, fossil fuel is over exploited and energy and environment problems become increasingly acute. Energy crisis and environment crisis have attracted concern of various countries. However, 70% of energy consumed by the whole world is wasted as waste heat. The energy shortage problem will be eased greatly if this waste heat can be recycled effectively. Thermoelectric material can convert thermal energy into electric energy, which is transmission parts-free, small in size, noise-free, pollution-free and of good reliability etc., and which has future prospect in recycling automobile waste heat and industrial surplus heat generation.

The conversion efficiency of thermoelectric material is determined by dimensionless thermoelectric merit figure (ZT=α²σT/κ, wherein, α is Seebeck coefficient, σ is conductivity, κ is thermal conductivity, T is absolute temperature, α²σ is called power factor). The greater ZT is, the higher the thermoelectric conversion efficiency of material is. According to the equation, in order to improve the properties of thermoelectric conversion materials, Seebeck coefficient and conductivity should be increased or thermal conductivity κ decreased.

The commercial cryogenic thermoelectric materials sold in the present market are Bi₂Te₃-based alloys. The ternary solid solution alloys are formed by adding Sb or Se to Bi₂Te₃. These alloys are with a conductivity between 0.8×10⁵ and 1.3×10⁵ Sm⁻¹, a Seebeck coefficient 160-220 μV/K, and a thermal conductivity 1.4-2.4 Wm⁻¹K⁻¹. As shown in FIG. 1 and FIG. 2, the ZT value of present Bi₂Te₃-base thermoelectric material is between 0.7 and 1.0, and thermoelectric conversion efficiency only reaches 5%-7%. Its main problem is the high thermal conductivity. And furthermore, with the temperature increasing, the resistance and thermal conductivity of the material will rapidly increase, which will influence thermoelectric properties of materials.

### SUMMARY OF THE INVENTION

In order to overcome the shortage of prior technology, the object of the present invention is to provide a BiSbTeSe-based thermoelectric material, which is formed by adding Se and another one or more metallic element to BiSbTe. This expands the application area of BiSbTeSe-based thermoelectric material with decreasing thermal conductivity and improving thermoelectric properties of materials.

In order to solve above problems, Some embodiments of the present invention are as follows:

A BiSbTeSe-based thermoelectric material, whose general formula is BiₘSbₙTeₓSe_{y}M_{z}; wherein, m=0.4-0.6, n=1.4-1.6, x=2.7-2.9, y=0.075-0.3, z=0.02-0.15, M is one or more elements of S, Si, P, Ge, Sn, Ce, Li, I, Br, Al, Cu, Ag, Yb, Tm, La, Gd and Dy.

Preferably, the mole percent of Bi, Sb, Se, Te and doping element M is: 8%-12%, 28%-32%, 54%-58%, 1.5%-6% and 0.4%-3% separately.

Another object of the present invention is to provide a preparation method of a BiSbTeSe-based thermoelectric material which can be got with low thermal conductivity, good thermoelectric properties and wide application. This preparation method can be achieved by following two methods.

A preparation method of a BiSbTeSe-based thermoelectric material comprises the steps of:

(1) mixing powder: putting elemental powder of Bi, Sb, Se, Te into a vacuum ball milling jar or a mixer jar with one or more kinds of elemental powder of S, Si, P, Ge, Sn, Ce, Li, I, Br, Al, Cu, Ag, Yb, Tm, La, Gd, Dy, and pumping vacuum to 10-1 pa or introducing argon, and mixing these materials by using a ball mill or a mixer.

(2) smelting alloy: putting the completed mixed powder mentioned above into a furnace tube of a CVD (Chemical Vapor Deposition) equipment, and pumping vacuum to 10-1 pa from it and heating it up to 1000° C.-1100° C., and melting and vaporizing raw powders, which will react and deposit in the furnace tube; the reaction time is 20 minutes, after the reaction is finished, cooling it naturally to room temperature, and the alloy ingot of BiSbTeSe-based thermoelectric material can be got.

A preparation method of a BiSbTeSe-based thermoelectric material includes steps of:

(1) mixing powder: putting elemental powder of Bi, Sb, Se, Te into a vacuum ball milling jar or a mixer jar with one or more kinds of elemental powder of S, Si, P, Ge, Sn, Ce, Li, I, Br, Al, Cu, Ag, Yb, Tm, La, Gd, Dy, and pumping vacuum to 10-1 pa or introducing argon, and mixing these materials by using a ball mill or a mixer;

(2) smelting alloy: putting the powder into a quartz tube with one end sealing, vacuumizing and sealing it; a manufacturer of a complete equipment of the sealing quartz tube is Walker Energy; melting the sealed quartz tube regionally under 700° C. for 20 h, and cooling it to room temperature, then the alloy ingot of BiSbTeSe-based thermoelectric material can be got.

Preferably, the purity of Bi, Sb, M, Se is 4N and 5N.

Preferably, in the process of mixing materials of step 1, the rotational speed of vacuum ball milling jar or mixer jar is 50 r/min, and the material mixing time is 2 h.

Preferably, the diameter of quartz tube of step 2 is between 20 mm and 30 mm.

Compared with the prior technology, beneficial effects of the present invention are as follows:

1. The BiSbTeSe-based thermoelectric material of this invention is of low thermal conductivity, good thermoelectric properties and wide application;

2. The BiSbTeSe-based thermoelectric material of this invention is of precisely temperature control, rapid response speed and long service life. It can also provide low-temperature environment for the usage of superconducting materials as well; for example, the BiSbTeSe-based thermoelectric material can be used in low temperature zone (room temperature −200° C). to generate power by utilizing heat (industrial surplus heat, waste heat, geothermal, solar energy), and which also can be used for small generating set used by special industries in field and remote area.

3. The BiSbTeSe-based thermoelectric material of this invention can also be used for preparing temperature-regulation system of micro power preparation, micro area cooling, optical communication laser diode as well as infrared sensor.

4. The present invention causes serious lattice distortion by adding Se and another one or more metallic element to BiSbTe ternary alloy P type thermoelectric material, which introduces a large number of defects to the Al-alloy crystal. These defects will play a prominent role in hindering the transmission of phonon in the process of vibration, which can effectively decrease thermal conductivity and improve thermoelectric properties of materials.

### BRIEF DESCRIPTION OF THE DRAWINGS

FIG. 1 shows a graph for measurement of ZT value of n-type and p-type Bi₂Te₃-based thermoelectric material;

FIG. 2 shows a thermoelectric conversion efficiency graph for Bi₂Te₃-based thermoelectric material;

FIG. 3 shows a graph for measurement of Seebeck coefficient of BiSbTeSe-based thermoelectric material in embodiment 1 of this invention;

FIG. 4 shows a graph for measurement of ZT value of BiSbTeSe-based thermoelectric material in embodiment 1 of the present invention;

FIG. 5 shows a micro crystal phase diagram for BiSbTeSe-based thermoelectric material in embodiment 1 of the present invention.

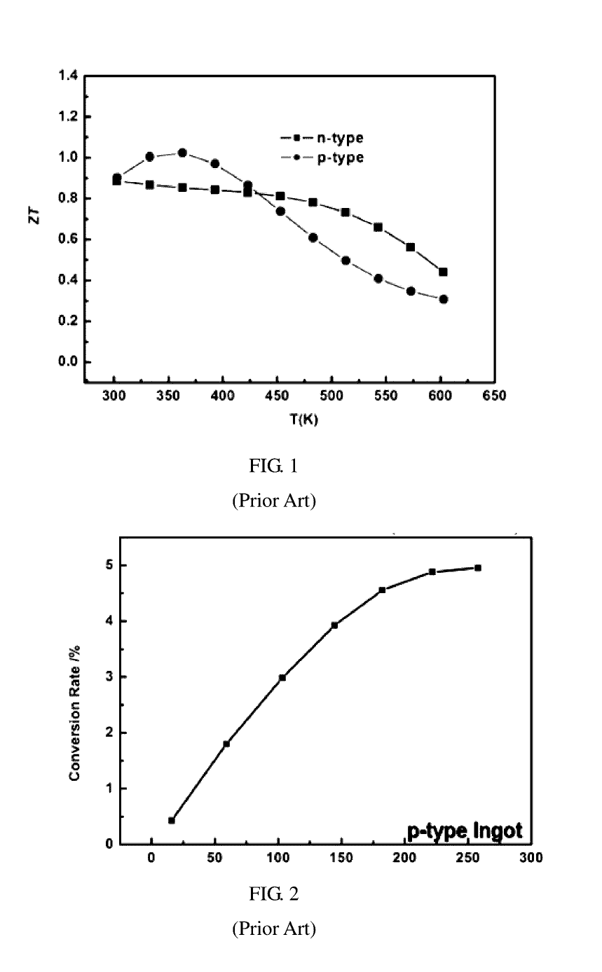

### DETAILED DESCRIPTION OF THE PREFERRED EMBODIMENTS

The present invention discloses a BiSbTeSe-based thermoelectric material, whose general formula is BiₘSbₙTeₓSe_{y}M_{z}; wherein, m=0.4-0.6, n=1.4-1.6, x=2.7-2.9, y=0.075-0.3, z=0.02-0.15, M is one or more elements of S, Si, P, Ge, Sn, Ce, Li, I, Br, Al, Cu, Ag, Yb, Tm, La, Gd and Dy.

Preferably, the mole percent of Bi, Sb, Se, Te and doping element M is: 8%-12%, 28%-32%, 54%-58%, 1.5%-6% and 0.4%-3% separately.

The BiSbTeSe-based thermoelectric material in this invention is an alloy formed by adding a proportion of one or more elements of Se and S, Si, P, Ge, Sn, Ce, Li, I, Br, Al, Cu, Ag, Yb, Tm, La, Gd to traditional BiSbTe ternary alloy thermoelectric material. Se is used for adjusting energy gap, which increases the Seebeck coefficient of material. In a conventional ternary solid solution alloys, the atomic radium of Bi is 1.70 Å (1 Å=10-10 m), and the atomic radium of Sb is 1.59 Å. As the atomic radium doesn't appear to be much different from that of Bi, the interior of traditional BiSbTe ternary alloy crystal is relatively complete, which is good for phonon transmission. That leads to high thermal conductivity of material, and influences material property. Nevertheless, the atomic radium of S is only 1.04 Å, which is much smaller than that of Bi and Sb. S atoms take the place of part Bi and Sb in BiSbTe ternary alloy, which will cause serious lattice distortion and introduce a large number of defects to alloy material crystal. These defects will play a prominent role in hindering the transmission of phonon in the process of vibration, and thus effectively decreasing thermal conductivity and improving thermoelectric properties of materials. Likewise, thermal conductivity can be decreased by adding one or more elements of Si, P, Ge, Sn, Ce, Li, I, Br, Al, Cu, Ag, Yb, Tm, La, Gd. These elements will take the place of any two elements in traditional BiSbTe, in which, these elements cause serious lattice distortion in occupied place and introduce defects to alloy material crystal.

Another object of the present invention is to provide a preparation method of a BiSbTeSe-based thermoelectric material which can be got with low thermal conductivity, good thermoelectric properties and wide application. This preparation method can be achieved by following two methods.

The preparation method of a BiSbTeSe-based thermoelectric material includes steps of:

(1) Mixing powder: putting elemental powder of Bi, Sb, Se, Te into a vacuum ball milling jar or a mixer jar with one or more kinds of elemental powder of S, Si, P, Ge, Sn, Ce, Li, I, Br, Al, Cu, Ag, Yb, Tm, La, Gd, Dy, and pumping vacuum to 10⁻¹ pa form it or introducing argon, and mixing these materials by using a ball mill or a mixer.

(2) Smelting alloy: putting the completed mixed powder into a furnace tube of a CVD (Chemical Vapor Deposition) equipment, and pumping vacuum to 10⁻¹ pa and heating it up to 1000° C.-1100° C., melting and vaporizing raw powders, which will react and deposit in the furnace tube; the reaction time is 20 minutes, after the reaction is finished, cooling it naturally to room temperature, and the alloy ingot of BiSbTeSe-based p-type thermoelectric material can be got.

A preparation method of a BiSbTeSe-based thermoelectric material includes steps of:

(1) mixing powder: putting elemental powder of Bi, Sb, Se, Te into a vacuum ball milling jar or a mixer jar with one or more kinds of elemental powder of S, Si, P, Ge, Sn, Ce, Li, I, Br, Al, Cu, Ag, Yb, Tm, La, Gd, Dy, and pumping vacuum to 10⁻¹ pa or introducing argon, and mixing these materials by using a ball mill or a mixer.

(2) smelting alloy: putting the powder into a quartz tube with one end sealing, vacuumizing and sealing it; a manufacturer of a complete equipment of the sealing quartz tube is Walker Energy; melting the sealed quartz tube regionally under 700° C. for 20 h, and cooling it to room temperature, then the alloy ingot of BiSbTeSe-based thermoelectric material can be got.

Preferably, the purity of Bi, Sb, M, Se is between 4N and 5N.

Preferably, in the process of mixing materials of step 1, the rotational speed of vacuum ball milling jar or mixer jar is 50 r/min, and the material mixing time is 2 h.

Preferably, the diameter of quartz tube of step 2 is between 20 mm and 30 mm.

In the following embodiments, the raw materials, instruments and equipment involved can be obtained by purchase channels.

### Embodiment 1

The preparation method of a BiSbTeSe-based thermoelectric material includes steps of:

(1) mixing powder: weighing 5 elemental powders with a purity reaching 4N in proportion of mole fraction of being 8%, 32%, 54%, 3% and 3% and putting them into vacuum ball milling jar, and pumping vacuum to 10⁻¹ pa or introducing argon, then mixing these materials by using a ball mill or a mixer. The rotational speed of vacuum ball milling jar is 50 r/min and material mixing time is 2 h.

(2) smelting alloy: putting the completed mixed powder mentioned above into a furnace tube of a CVD (Chemical Vapor Deposition) equipment, and pumping vacuum to 10⁻¹ pa from it and heating it up to 1000° C.-1100° C., then melting and vaporizing raw powders which will react and deposit in the furnace tube; the reaction time is 20 minutes; after the reaction is finished, cooling it naturally to room temperature, and the alloy ingot of BiSbTeSe-based p-type thermoelectric material can be got, and the general formula of which is Bi_{0.4}Sb_{1.6}Te_{2.7}Se_{0.15}S_{0.15}.

### Embodiment 2

The preparation method of a BiSbTeSe-based thermoelectric material includes steps of:

(1) mixing powder: weighing 5 elemental powders with a purity reaching 5N in proportion of mole fraction of being 12%, 28%, 58%, 1.5% and 0.5% and putting them into a vacuum ball milling jar, and pumping vacuum to 10⁻¹ pa or introducing argon, then mixing these materials by using a ball mill or a mixer. The rotational speed of vacuum ball milling jar is 50 r/min, and material mixing time is 2 h.

(2) smelting alloy: putting the powder into a quartz tube having a diameter of 25 mm with one end sealing, and vacuumizing and sealing it; a manufacturer of a complete equipment of the sealing quartz tube is Walker Energy; melting the sealed quartz tube regionally under 700° C. for 20 h, and cooling it naturally to room temperature, and the alloy ingot of BiSbTeSe-based thermoelectric material can be got, and the general formula of which is Bi_{0.6}Sb_{1.4}Te_{2.9}Se_{0.3}S_{0.025}

1. Thermal Conductivity Measurement

Thermal conductivity of BiSbTeSe-based thermoelectric materials is measured in embodiment 1 and embodiment 2. The instruments adopted are American TA, laser thermal conductivity measurement instrument FL4010 and Netzsch DSC 200F3. These instruments are used to test thermal conductivity of BiSbTeSe-based p type thermoelectric material separately under 50° C. [symbol] 80° C. [symbol] 120° C., and the results are shown in table 1.

TABLE 1
Thermal conductivity measurement result

| | project | | |
|---|---|---|---|
| | Thermal conductivity ( W/m · K) | | |
| Embodiments | 50° C. | 80° C. | 120° C. |
| Embodiment 1 | 0.49617 | 0.64987 | 0.62583 |
| Embodiment 2 | 0.47158 | 0.63975 | 0.62274 |

2. Resistance Measurement

The method of measuring resistance is to prepare block by cool-pressing and Spark Plasma Sintering (SPS) BiSbTeSe-based thermoelectric materials in embodiment 1 and embodiment 2 with a four-point probe resistance tester (Suzhou Jingge, ST2722) to measure resistance, and the results are shown in table 2.

TABLE 2
Resistance measurement

| | project | |
|---|---|---|
| | resistance (Ω · m) | |
| | Cold | SPS |
| Embodiments | pressing sample | sintering sample |
| Embodiment 1 | 9.742 × 10⁻⁶ | 8.132 × 10⁻⁶ |
| Embodiment 2 | 9.158 × 10⁻⁶ | 7.870 × 10⁻⁶ |

3. Seebeck Coefficient

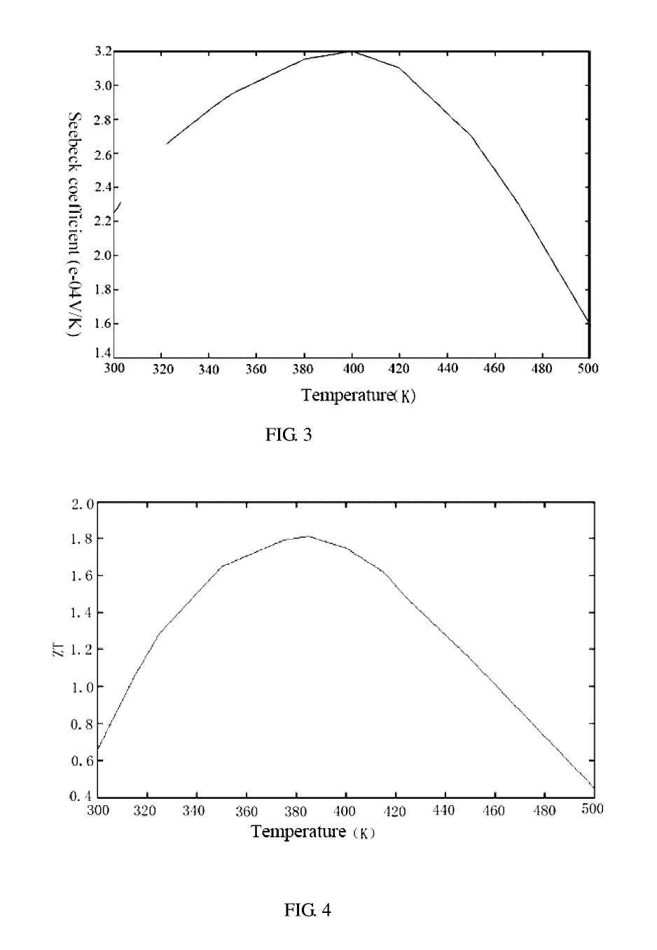

Seebeck coefficient instrument produced by Japanese ULBAC-RIKO company is used to test BiSbTeSe-based p type thermoelectric material in embodiment 1. Measurement temperature is between 50 and 200° C. and the measuring method of resistance is four-electrode measuring method. The measurement results of the graphs of Seebeck coefficient and thermoelectric merit figure ZT are shown in FIG. 3 and FIG. 4 respectively.

4. Phase Diagram of Material

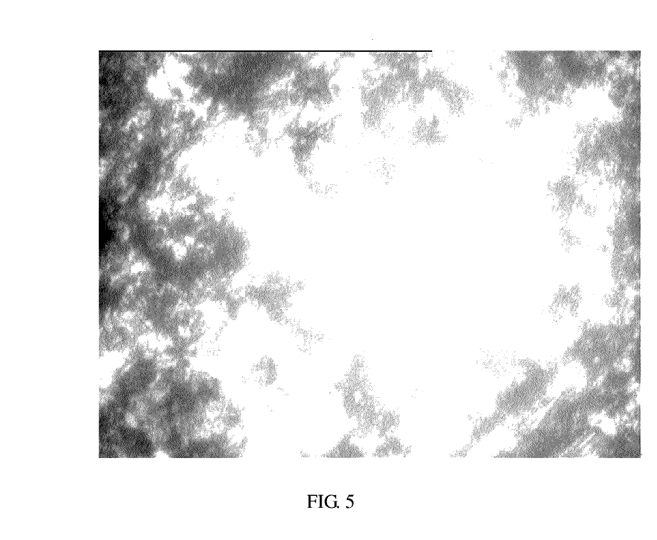

FIG. 5 is a micro phase diagram of BiSbTeSe-based p type thermoelectric material in embodiment 1, and the measurement instrument is metallographic microscope HOK-0731 manufactured by Guangzhou Haikesi Automatic Equipment Co., Ltd. After polishing the surface of a piece of melted alloy with abrasive paper #1500, this instrument can be used to capture crystal image of material with its camera system, and the result is shown in FIG. 5.

Various modifications could be made to the embodiments by those of ordinary skill in the art without departing from the true spirit and scope of the disclosure. And those modified embodiments are covered by the claims of the disclosure.

What is claimed is:

1. A BiSbTeSe-based thermoelectric material, wherein, the thermoelectric material's general formula is BiₘSbₙTeₓSe_{y}M_{z}; wherein, m=0.4-0.6, n=1.4-1.6, x=2.7-2.9, y=0.075-0.3, z=0.02-0.15, M is one or more elements of S, Si, P, Ge, Sn, Ce, Li, I, Br, Al, Cu, Ag, Yb, Tm, La, Gd and Dy.

2. The BiSbTeSe-based thermoelectric material according to claim 1, wherein, the mole percent of Bi, Sb, Se, Te and doping element M is: 8%-12%, 28%-32%, 54%-58%, 1.5%-6% and 0.4%-3% separately.

3. A preparation method of BiSbTeSe-base thermoelectric material of claim 1, comprising steps of:
(1) mixing powder: putting elemental powder of Bi, Sb, Se, Te into a vacuum ball milling jar or a mixer jar with one or more kinds of elemental powder of S, Si, P, Ge, Sn, Ce, Li, I, Br, Al, Cu, Ag, Yb, Tm, La, Gd, Dy, and pumping vacuum to 10⁻¹ pa or introducing argon, then mixing these materials by using a ball mill or a mixer; and
(2) smelting alloy: putting the completed mixed powder into a furnace tube of a CVD (Chemical Vapor Deposition) equipment, then pumping vacuum to 10⁻² pa from it and heating it up to 1000° C.-1100° C., melting and vaporizing raw powders which will react and deposit in the furnace tube; the reaction time is 20 minutes; after the reaction is finished, cooling it naturally to room temperature, and the alloy ingot of BiSbTeSe-based thermoelectric material can be got.

4. A preparation method of a BiSbTeSe-based thermoelectric material according to claim 1, comprising steps of:
(1) mixing powder: putting elemental powder of Bi, Sb, Se, Te into a vacuum ball milling jar or a mixer jar with one or more kinds of elemental powder of S, Si, P, Ge, Sn, Ce, Li, I, Br, Al, Cu, Ag, Yb, Tm, La, Gd, Dy, and pumping vacuum to 10⁻¹ pa from the tube or introducing argon into it, and then mixing these materials by using a ball mill or a mixer;
(2) smelting alloy: putting the powder into a quartz tube with one end sealing, vacuumizing and sealing it; a manufacturer of a complete equipment of the sealing quartz tube is Walker Energy; melting the sealed quartz tube regionally under 700° C. for 20 h, and cooling it naturally to room temperature, then the alloy ingot of BiSbTeSe-based thermoelectric material can be got.

5. The preparation method according to claim 3, wherein, the purity of the elemental Bi, Sb, Se and Te is between 4N and 5N.

6. The preparation method according to claim 4, wherein, the purity of the elemental Bi, Sb, Se and Te is between 4N and 5N.

7. The preparation method according to claim 3, wherein, in the material mixing process of step 1, the rotational speed of vacuum ball milling jar or mixer jar is 50 r/min, and the material mixing time is 2 h.

8. The preparation method according to claim 4, wherein, in the material mixing process of step 1, the rotational speed of vacuum ball milling jar or mixer jar is 50 r/min, and the material mixing time is 2 h.

9. The preparation method according to claim 4, wherein, a diameter of quartz tube is between 20 mm and 30 mm.
